(19) United States
(12) Patent Application Publication
(10) Pub. No.: US 2008/0089267 A1
(43) Pub. Date: Apr. 17, 2008

(54) MULTI-ANTENNA UPGRADE FOR A TRANSCEIVER

(75) Inventors: Weijun Zhu, Los Angeles, CA (US); Oscar Y. Takeshita, Los Angeles, CA (US); David Fogelsong, Sunland, CA (US); Sandeep Sasi, Los Angeles, CA (US); Jatin Bhatia, Los Angeles, CA (US)

Correspondence Address: GANZ LAW, P.C., P O BOX 2200, HILLSBORO, OR, 97123, US

(73) Assignee: SILVUS COMMUNICATIONS SYSTEMS, INC., Los Angeles, CA (US)

(21) Appl. No.: 11/852,985

(22) Filed: Sep. 10, 2007

Related U.S. Application Data
(60) Provisional application No. 60/826,468, filed on Sep. 21, 2006.

(51) Int. Cl. H04B 7/14; G01R 29/08

(52) U.S. Cl. 370/315; 343/703

(57) ABSTRACT

Disclosed is a radio repeater system that utilizes a number of spatially diverse receiving antennas, a signal measuring system associated with each of the antennas, a weighted signal combining means, with amplification and retransmission. The system operates by monitoring each of receiving antennas and then calculating the weighted inputs in the signal combining subsystem. The calculation of the weighted inputs is performed by any one of a number of methods, including maximum ratio combining (MRC), minimum mean square error combining (MMSE), and other methods.

### RELATED APPLICATIONS

This application claims the benefit of and priority to U.S. Provisional Application Ser. No. 60/826,468 filed on Sep. 21, 2006, by Zhu et al, entitled MULTI-ANTENNA UPGRADE FOR A TRANSCEIVER, the contents of which are hereby incorporated by reference as if recited in full herein for all purposes.

### BACKGROUND

The present device is related to the field of radio wave data communication devices in general and radio signal repeaters in particular.

Wireless Local Area Networking (WLAN) is a popular method of computer communications. Several methods of Wireless Local Area Networking communications exist and are well known in the arts. The frequency and communication protocols are typically defined by a standards body to ensure interoperability between devices. For example, “WiFi” and “WiMax” are common names for frequency and protocols for data transmission standards.

A repeater is well known in the radio communication arts. The purpose of a repeater is to receive the signal from a transmitting source, amplify the signal, then retransmit the signal to a receiver. The resulting stronger signal from the output of the repeater increases the range in which a receiver can receive a signal.

When data signals are transmitted, such as WLAN signals, current repeater design involves the reception of the incoming attenuated signal, decoding the signal, and then reencoding the amplified signal. This leads to interoperability problems because the due to the inherent processing capabilities of the repeaters.

As is well known in the arts, a typical system configuration in a WLAN system is shown in the prior art FIG. 1. In this WLAN System 100 an access point 110 transmits data to a single antenna client 120. Likewise, the single antenna client 120 transmits data to the access point 110, completing the communications cycle. Typically, the access point 110 is implemented as a wireless router. The client 120 is usually a computer with a plug-in and/or integrated wireless card.

When data is transmitted from the access point 110 to the client 120 is termed a ‘downlink’ 130 of data. When data is transmitted from the client 120 to the access point 110 it is an ‘uplink’ 140 of data. The cyclic process of the downlink of data and the uplink of data between the access point 110 and the client 120 creates a communications channel that allows for the exchange of electronic information.

WLAN systems can suffer from the degradation of signal quality. When signal quality degrades, the ability to transmit information is reduced. Signal quality is determined by a number of factors, including, the power of the transmitter at the access point 110 and the gain of the receiver at the client 120 during the downlink. Other factors affecting signal quality include the distance between the transmitter and receiver, and the topography between the transmitter and receiver. In a metropolitan area, the topography may not only consist of tall buildings but may also include subterranean structures. Also affecting the signal quality is the number of other signals that are transmitting on the same frequency and that interfere with the signal. Signal quality is both spatially and temporally variant with mobile clients and/or access points. There are changing signal characteristics as the client moves from one topography point to another. This variation in signal quality is known as “fading”.

Fading of the signal, in a scattering environment, is not unusual in a metropolitan area. Fading is uncorrelated in space when the separation is more than ½ wavelength for multi-antenna configurations. (see W. C. Jakes, “New Techniques for mobile radio”, Bell Laboratory Rec., pp. 326-330, December 1970). Transmission of a radio signal becomes uncorrelated in space if the separation is larger than ½ a wavelength.

A way to reduce signal fading is to employ multiple antennas that are separated by more than one half of a wavelength. It is well known in the arts that the use of multiple antennas improves signal quality for either the access point or the client. When signals are transmitted from multiple antennas, there is a decrease in the risk of fading. Multiple antennas also allow incoming signals to be combined to produce a stronger signal. When multiple antennas are used for both the access point 110 and the client 120, this configuration is known as “MIMO” (multiple in, multiple out).

As shown in prior art FIG. 2, a passive MIMO type radio subsystem 200 consists of a signal path 205, signal processing module 210, and a phase antenna array interface 215, and multiple antennas 220′, 220″, 220″′. Downlink data is transmitted on the signal path 205 and processed by the module 210. The signal is then fed to the antenna array and transmitted on the antennas 220.

As shown in prior art FIG. 3, an active MIMO type radio subsystem 300 consists of a signal path 305, a signal processing module 310, several antennas 320′, 320″, and 320″′. Downlink data is transferred from signal path 305 to the antennas 320, alternately uplink data is transferred from antennas 320 to the signal processing module.

Therefore, to increase the signal strength of single antenna systems and by complementing them with MIMO efficiencies; a repeater with MIMO capabilities is proposed that can be easily installed in front of the transmitting WLAN. This repeater configuration is termed a “multi-antenna extender”.

### SUMMARY

The inventive subject matter overcomes problems in the prior art by providing a multi-antenna extender with the following qualities, alone or in combination:

The features of the multi-antenna extender are at least two input antennas, a processor controller, a radio frequency combiner, a summation module, and a radio frequency transmitter. The processor controller may be configured to read the signal value on each of the input antennas and then create a new signal using various algorithms as implemented in software or firmware in the processor controller. These algorithms include the maximum ratio combining (MRC), and the minimum mean square error combining (MMSE) with interference suppression. Methods of using the multi-antenna extender are also described that illustrates the position of the device for the purpose of extending the radio signal strength.

These and other embodiments are described in more detail in the following detailed descriptions and the figures.

The foregoing is not intended to be an exhaustive list of embodiments and features of the present inventive subject matter. Persons skilled in the art are capable of appreciating other embodiments and features from the following detailed description in conjunction with the drawings.

### BRIEF DESCRIPTION OF THE DRAWINGS

FIG. 1 is a prior art block diagram of Access Point and a Single Client System.

FIG. 2 is a prior art block diagram of a MIMO antenna system that uses a passive antenna array.

FIG. 3 is a prior art block diagram of a MIMO antenna system that uses an active antenna array.

FIG. 4 is a block diagram of the multi-antenna extender configured to downlink information from the access point to the computer.

FIG. 5 is a block diagram of the multi-antenna extender configured to uplink radio signals from the computer to the access point.

FIG. 6 is a block diagram of the multi-antenna extender configured to select between “n” antenna inputs based on signal strength.

FIG. 7 is a block diagram of the multi-antenna extender configured to use a weighting of values of “n” receiving antennas.

FIG. 8 is a generalized flowchart showing the calculation and weighting of the factors in the RF combiner.

FIG. 9 is a generalized flowchart showing the calculation and weighting of the factors in the RF combiner using the maximum ratio combining algorithm.

FIG. 10 is a generalized flowchart showing the calculation and weighting of the factors in the RF combiner using the minimum mean square error method, with interference suppression.

FIG. 11 shows a configuration of the multi-antenna extender where two extenders are used to allow a greater distance between the access point and the client.

FIG. 12 shows a configuration with a multiple of multi-antenna extenders arranged in parallel to increase the bandwidth of the transmission path.

### DETAILED DESCRIPTION

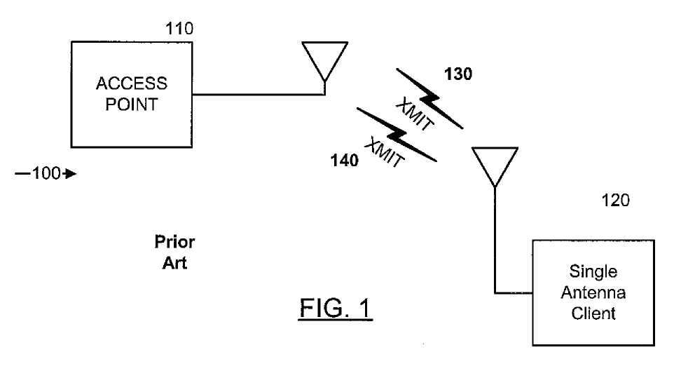

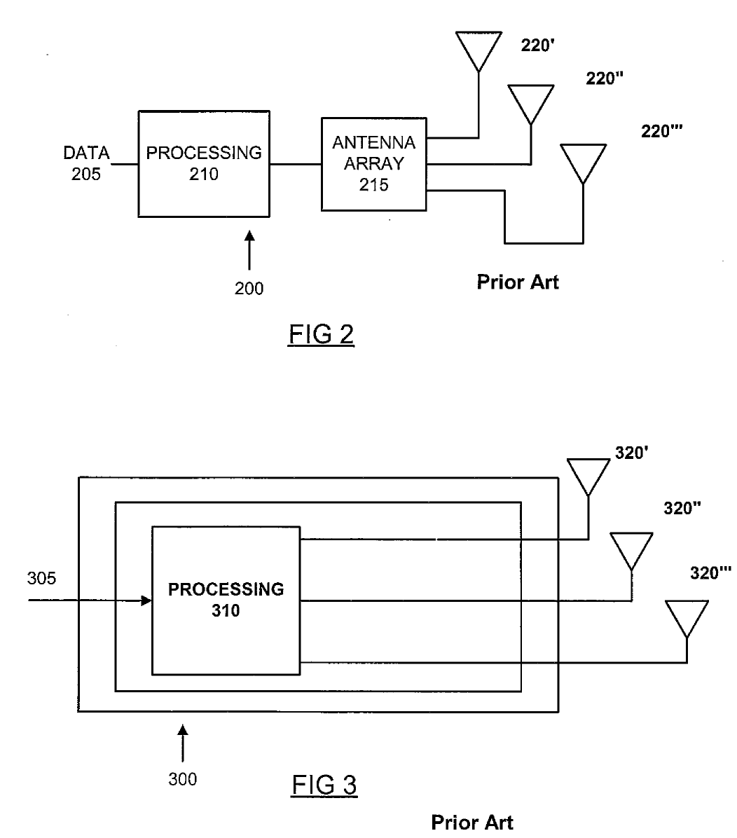

Representative embodiments according to the inventive subject matter are shown in FIGS. 1 to 12 wherein similar features share common reference numerals.

In certain respects, the inventive subject matter provides a Multiple Input Multiple Output (MIMO) capabilities to an existing single antenna WLAN environment. The inventive subject matter also provides a cost effective method of upgrading a computing network to provide MIMO capabilities.

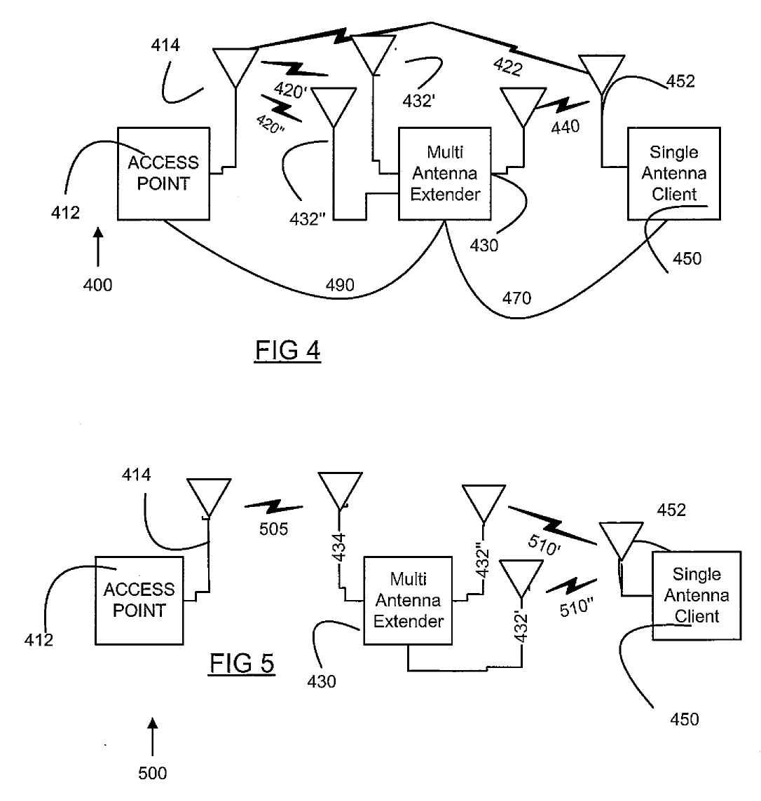

FIG. 4 depicts a block diagram 400 as shown with the multi-antenna extender 430 operating in “downlink” mode in accordance with the inventive subject matter. WLAN signals 420′, 420″, and 422 are generated by the access point (‘ap’) 412 and transmitted on the access point antenna 414. A portion of the signals transmitted on the access point antenna 414 are received by the multi-antenna extender receiving antennas 432′, 432″, whereas another portion of the signals transmitted are received by the single antenna client 452. Although two multi-antenna extender antennas 432′, 432″ are shown it is generally understood that any practical number of antennas may be implemented.

The ap-mae physical distance 490 from the access point 412 to the multi-antenna extender 430 can be increased since the received signal strength on the multi-antenna extender consists of processing the received WLAN signals 420′ and 420″ simultaneously using a MIMO type subsystem as shown in the prior art.

The multi-antenna extender 430 then retransmits the signal 440 from the multi-antenna extender 430 to the antenna of the single-antenna client (“sac”) 450. Physically, the mae-sac distance 470 can be relatively small and in all likelihood is a line of site connection. This short physical mae-sac distance 470 results in a low loss of signal strength.

Now referring to FIG. 5. In FIG. 5 a block diagram 500 is shown with the multi-antenna extender 430 operating in “uplink” mode. The sac 450 transmits on the antenna 452 the uplink signal 510′, 510″. The uplink signal 510′,510″ is received by the multi-antenna extender 430 via the multiple antennas 432′, 432″ and retransmitted on the single antenna 434 as signal 505. This signal is received by the single antenna ap 412 by the antenna 414.

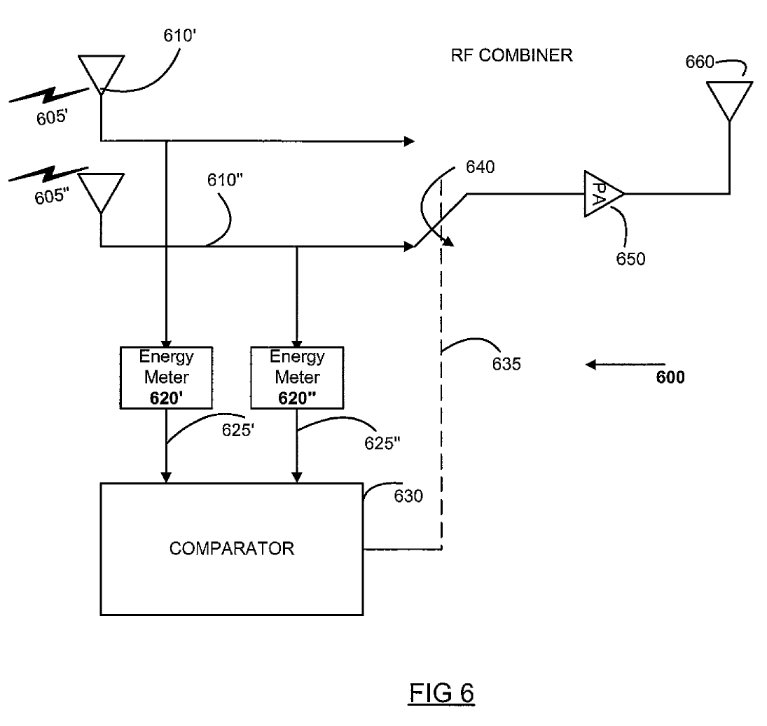

Now referring to FIG. 6. FIG. 6 being the preferred embodiment of the multi-antenna extender 430. The system diagram 600 of the multi-antenna extender consists of the physically diverse antennas 610′,610″ receiving radio signals 605′, 605″′. Connected to the physically diverse antennas 610′, 610″ are energy meters 620′,620″ respectively. The output of the energy meters 620′,620″ is the signal strength 625′,625″ for each signal respectively. The signal strength 625′, 625″ is connected to the n-input comparator 630. The output of the n-input comparator is a switch signal 635 that controls a multi-selector switch 640. The multi-selector switch 640 controls the pathway of the radio signals 605 to signal amplifier 650. The signal amplifier 650 consists of an input and an output. The output of the signal amplifier 650 is a signal transmitted on the antenna 660.

The term “connected to” may be, but is not limited to, an electrical, optical, or wireless connection between the objects being connected.

During operation the n-input comparator continually samples outputs from each energy meter 620′, 620″ . . . 620^{N}. When the signal value for one energy meter 620 exceeds the others, the multi-selector switch 640 selects the corresponding antenna 610 with the highest signal value. The radio signal 605 is then passed through to the signal amplifier and transmitted on antenna 660.

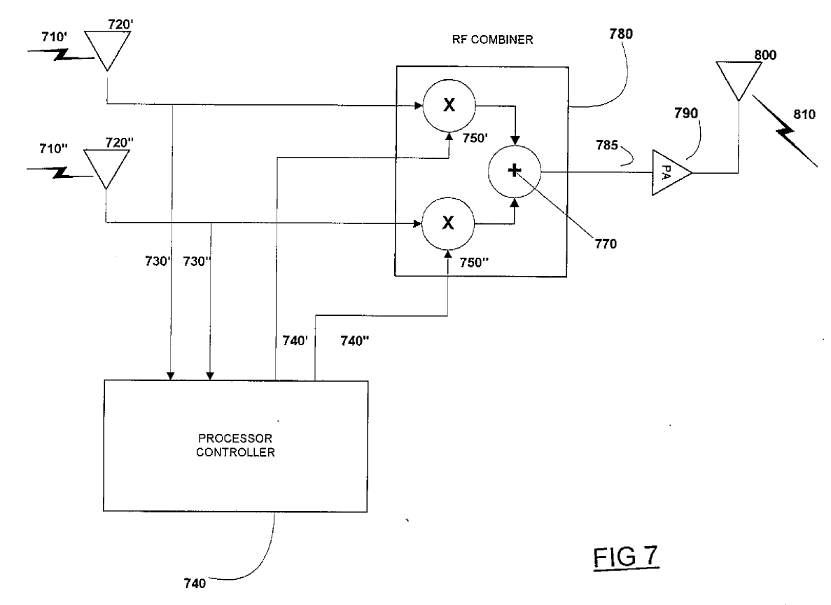

Now referring to FIG. 7, which depicts another embodiment of the multi-antenna extender. Radio signals 710′,710″ are received by antennas 720′, 720″ that are spatially diverse. The radio signals 720′ and 720″ are input to a processor controller 740 and the RF combiner 780. The RF combiner 780 is connected to a Power Amplifier 790 and an antenna 800.

The processor controller 740 has a number of radio input signals 730′,730″ corresponding to each receiving antenna. Software within the processor controller 740 continuously measures the input signals 730′,730″ generating weighting factors 750′,750″. The weighting factors 750′, 750″ are connected to the RF Combiner 780.

The RF combiner 780 has two sets of inputs and one output. The first set of inputs to the RF combiner are the radio input signals 730′, 730″ and the second set of inputs are the weighting factors form the processor controller 740. The combiner output 785 from the RF Combiner 780 is a weighted sum of the received signals from the radio input signals 730′, 730″.

The combiner output 785 is connected to a power amplifier 790 that transmits and repeats the radio signal on the antenna 800. The antenna 800 transmits the repeated signal 810. The repeated signal being a weighted combination of the radio input signals 730′ and 730′.

This implementation is shown with two antennas for simplicity, but any number of antennas may be utilized for the desired reception and amplification of the radio input signal.

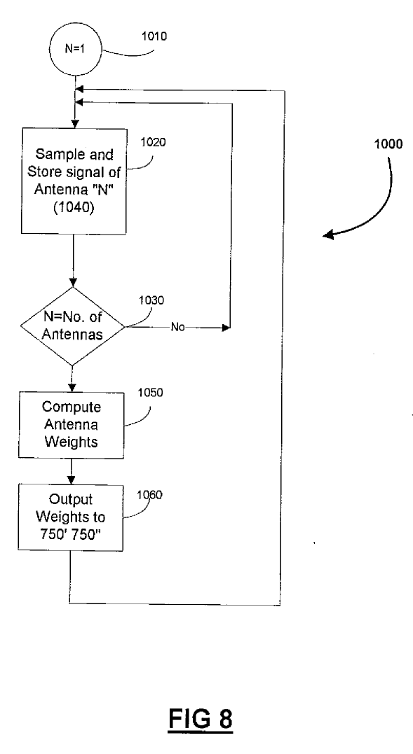

Now referring to FIG. 8 which is a generalized flowchart of an embodiment as shown in FIG. 7. Here the processor/controller program (1000) in the processor controller 740 scans each of the antennas 730′, 730″ (Steps 1010, 1020, 1030) and stores the signal of each antenna (Step 1040) in the processor controller 740. After the signal of each antenna has been measured, then the computed antenna weights (Step 1050) are generated. The computed antenna weights 1050 are then applied to the RF Combiner 780 as weighting factors 750′, 750″.

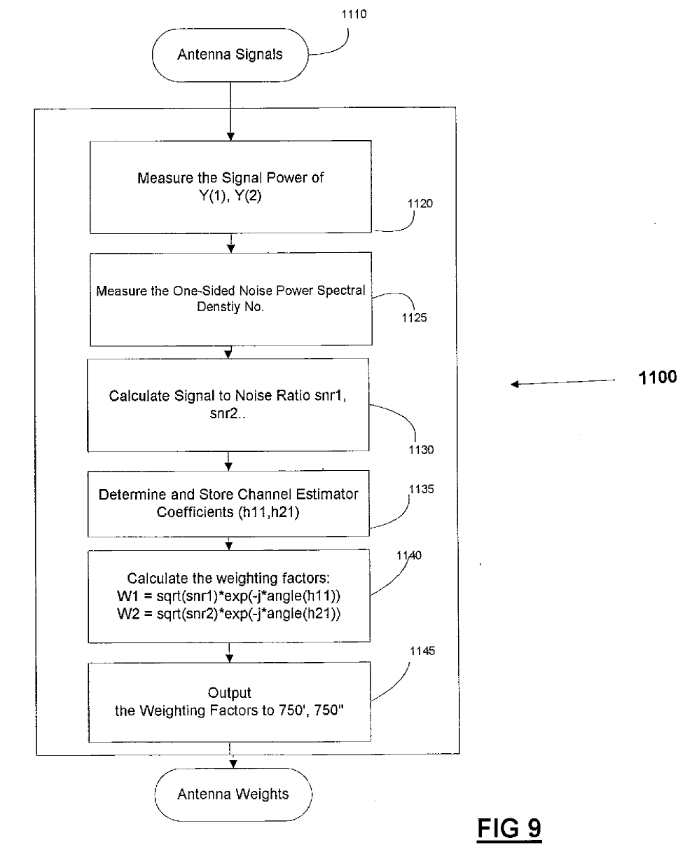

Now referring to FIG. 9, showing an embodiment of the processor/controller program 1000 as illustrated in FIG. 8 utilizing the maximum ratio combining (MRC).

The desired signal x1 (e.g. the signal that leaves the antenna at the transmitter) arrives at each of the receiving antennas Y1, Y2, (etc) with varying levels. The signals Y1, Y2 as measured by the multi antenna extender as the signal input. The desired signal x1 arrives at each antenna with a different power and signal phase because of different channel coefficients h11 and h21.
Y1=x1*h11+n1
Y2=x1*h21+n2

The received signals are also corrupted by noise n1 and n2. The channel coefficients h11 and h21 can be computed with a channel estimator. The MRC algorithm then performs the combining of the incoming signals after weighting each signal path with a factor that is proportional to the square root of its signal to noise ratio snr1 and snr2. In addition, the weighting also aligns the phase of the incoming signals. Therefore the weighting factors are:
W1=sqrt(snr1)*exp(−j*angle(h11))
W2=sqrt(snr2)*exp(−j*angle(h21))
Where angle( ) is the phase of the argument. The combined signal to be amplified and forwarded becomes
Z=W1*Y1+W2*Y2

Now referring to FIG. 9 showing the flowchart implementing the maximal ratio combining (MRC) algorithm. In the first step, the signal strength is computed on receiving antennas Y1, Y2 (Step 1120), next the one sided noise power spectral density No is computed (Step 1125), the signal to noise ratio of each antenna input is then computed snr1, snr2 (Step 1130). Next the channel estimator coefficients are determined h11, h21 (Step 1135). The weighting factors are then determined by multiplying the signal to noise ratio snr1, snr2 by the phase angle (Step 1140). The weighting factors are then set in the RF combiner (Step 1145).

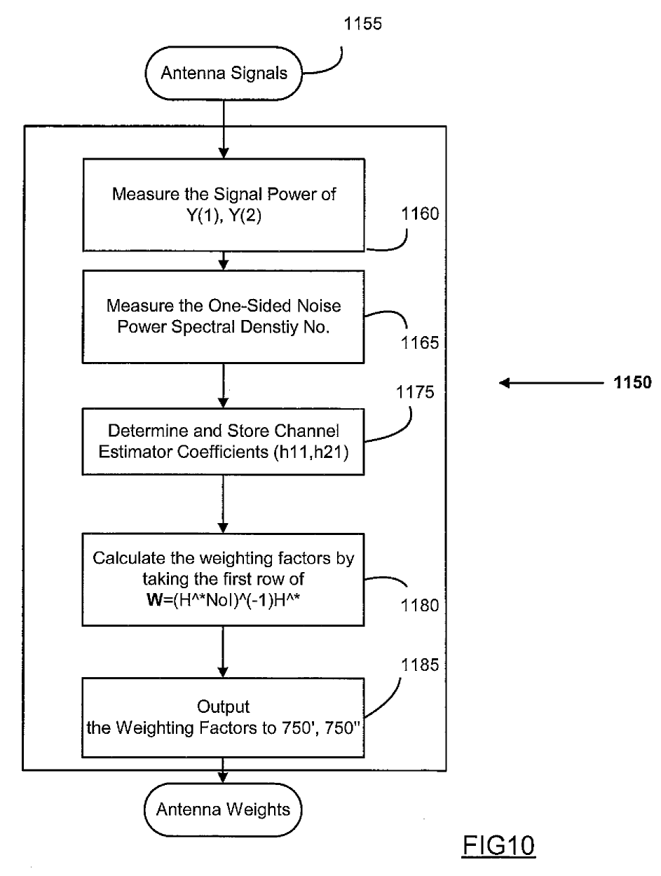

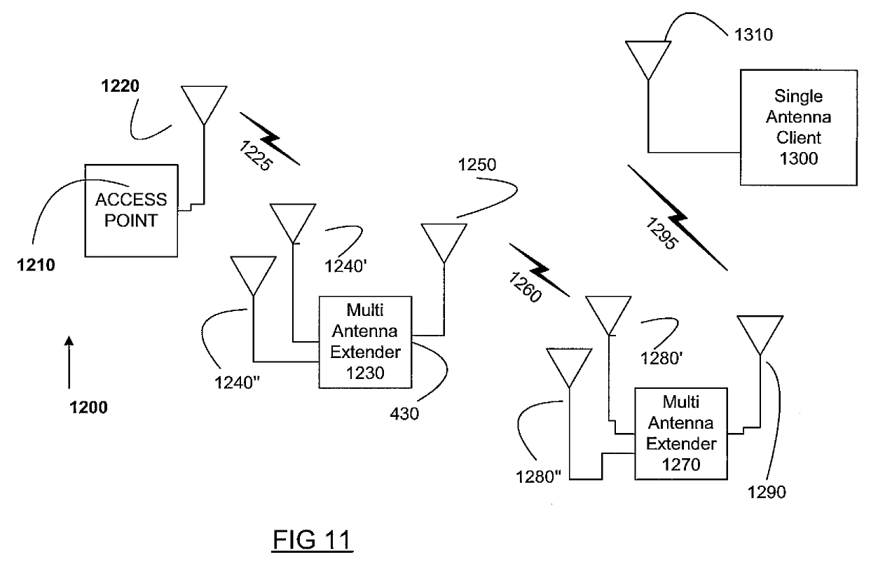

Now referring to FIG. 10, showing an embodiment of the processor controller program 1000 as illustrated in FIG. 8 utilizing the minimum mean square error combining (MMSE) with interference suppression.

The MMSE algorithm can be used to mitigate the effect of interference. The signals Y1, Y2 as measured by the multi antenna extender (MAE) as the signal input. The desired signal x1 arrives at each antenna with a different power and signal phase because of different channel coefficients h11 and h21. In addition to the desired signal x1 arriving at the repeater, an interference signal x2 may also arrive at the MAE with different power and signal phases because of channel coefficients h12 and h22. Therefore, the signals Y1,Y2 are represented by:
Y1=x1*h11+x2*h12+n1
Y2=x1*h21+x2*h22+n2

In matrix notation, the above becomes:
Y=Hx+n

Where Y=[Y1 Y2]ˆT, x=[x1 x2]ˆT, n=[n1 n2]ˆT, and H=[hij] a 2×2 matrix whose entry in the ith row and jth column is hij (ˆT means that the vector is transposed).

The weighting coefficients W=[W1 W2] are computed so as to minimize the signal to interference plus noise ratio (SINR). It is well known in the art that the MMSE solution is given by:
W=(Hˆ*H+No I)ˆ(−1)Hˆ*

Where ˆ* denotes transpose conjugate, No is the one-sided power spectral density, and I is a 2×2 identity matrix. W is then the first row of W.

Now referring to FIG. 10 showing the flowchart 1150 implementing the minimum mean square estimation algorithm (MMSE) with interference suppression.

In the first step, the signal strengths are measured on receiving antennas Y1, Y2 (Step 1160), next the one sided noise power spectral density No is computed (Step 1165), next determine and store the Channel Estimator Coefficients h11, h12, h21, h22 (Step 1175). The next stop calculates the weighting factors by taking the first row of the resulting matrix W from the matrix calculation (Hˆ*H+NoI)ˆ(−1)Hˆ*. (Step 1180). The weighting factors are then output to 750′,750″ (Step 1185).

Additional embodiments of the processor controller program includes: a) the regeneration of the signal prior to forwarding; b) a translation in frequency prior to forwarding; c) processing of input signals and forwarding on multiple antennas; d) use of directional antennas.

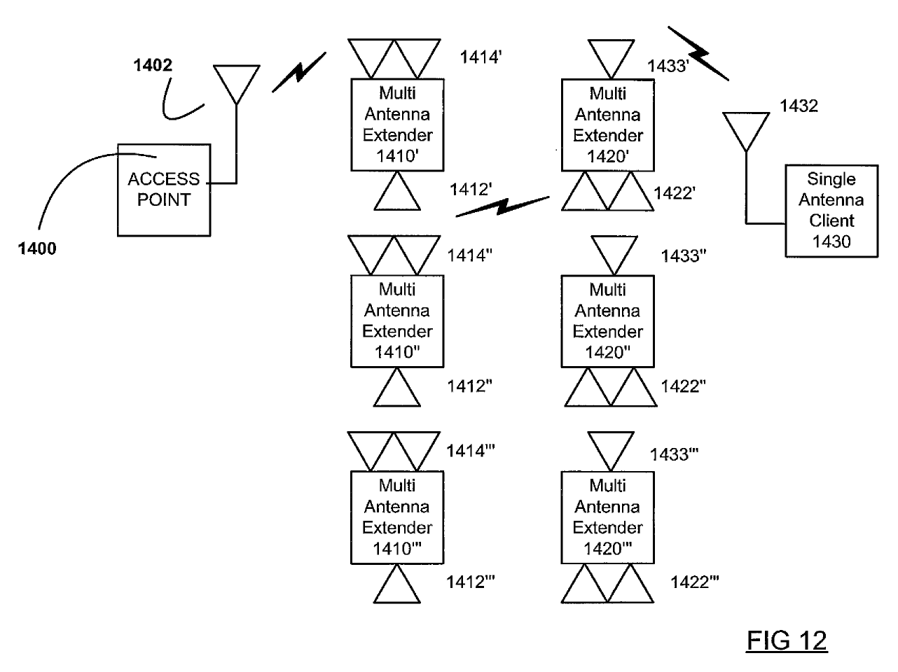

Now referring to FIGS. 11 and 12 each showing different configurations of multi-antenna extenders to improve communications performance.

In FIG. 11 a system 1200 consists of an access point 1210 with a transmitting antenna 1220. A local multi-antenna extender 1230 consists of “n” local receiving antennas 1240′, 1240″ and one transmitting antenna 1250. A remote multi-antenna extender 1270 consists of “n” remote receiving antennas 1280′, 1280″ and a single remote transmitting antenna 1290. The signal 1295 from the single remote transmitting antenna 1290 is transmitted to the single-antenna client 1300 antenna 1310.

Now referring to FIG. 12 a bank of local multi-antenna extenders 1410 are configured near the access point 1400 and a bank of remote multi-antenna extenders 1420 are configured near the single antenna client 1430. In this configuration the signal path begins at the access point antenna 1402 which is transmitted to each of the local multi-antenna extenders 1410′, 1410″, 1410″′, etc. receiving antennas 1414′, 1414″, 1414″′. The signal is forward on the antennas 1412′, 1412″, 1412″′, after being internally processed in the local multi-antenna extender 1410. The forwarded signals are received by the multiple antennas 1422 located on each remote multi-antenna extenders 1420. The forward signal is processed and transmitted to the single access client 1430 with antenna 1432.

Persons skilled in the art will recognize that many modifications and variations are possible in the details, materials, and arrangements of the parts and actions which have been described and illustrated in order to explain the nature of this inventive concept and that such modifications and variations do not depart from the spirit and scope of the teachings and claims contained therein.

All patent and non-patent literature cited herein is hereby incorporated by references in its entirety for all purposes.

1. An antenna extender comprising:
at least two radio frequency inputs, each capable of coupling with an antenna, each input, the extender being configured to provide a modified value for each input, and a summation of the modified values for providing a single radio frequency output;
wherein the extender provides modified values in real time by measuring the radio frequency inputs and providing for each input a weight to be applied to the radio frequency inputs for use in summation.

2. The antenna extender as in claim 1 wherein said extender further comprises a computational unit, said computational unit providing the modified values as determined by using the maximum ratio combining algorithm.

3. The antenna extender as in claim 1 wherein said extender further comprises a computational unit, said computational unit providing the modified values as determined by using the minimum mean square error with interference suppression.

4. The antenna extender as in claim 1 wherein said wherein said antenna extender further comprises a computational unit, said computational unit providing the modified values in binary fashion as determined by measuring the total energy of the radio frequency input.

5. The antenna extender as in claim 1 wherein at least two antennas are coupled on a one-to-one basis to each input.

6. The antenna extender as in claim 5 wherein said antenna extender further comprises a caching unit, said caching unit interposed between the antenna and the input.

7. The antenna extender as in claim 5 where said radio frequency combiner further comprises a frequency translation unit, said frequency translation unit interposed between said antenna and said radio frequency input, said frequency translation unit able to alter the frequency of the signal on the antenna.

8. The antenna extender as in claim 1 where said radio frequency output is coupled to one or more antennas.

9. The antenna extender as in claim 8 where an amplifier is interposed between said radio frequency out and the antennas.

10. A method for relaying radio signals using an antenna extender, said method comprising:
receiving input radio signals on a multiplicity of antennas;
weighting each of the individual radio signals in the frequency domain;
summing each of the individual radio signals to create a composite signal;
retransmitting the composite radio signal;
whereby there is a minimal delay between the input radio signals and the composite radio signals.

11. The method of claim 11 wherein said composite signal is further modified by an algorithm, the algorithm selected from a group consisting of the maximum ration combining algorithm and the minimum mean square error with interference suppression algorithm.

12. An antenna extender for relaying radio signals, which comprises:
means for receiving radio wave signals on more than one antenna,
means for measuring the each signal on each antenna,
means for determining a separate signal weight based on the signal on each antenna,
means for creating a weighted signal by multiplying the separate signal weight with the signal from each antenna
means for creating an output signal by summing all of the weighted signals.

13. An antenna extender for relaying radio signals as in claim 12, further comprising the means for determining the signal weights by using the maximum ratio combining algorithm.

14. An antenna extender for relaying radio signals as in claim 12, further comprising the means for determining the signal weights by using the minimum mean square error with interference suppression.

15. An antenna extender for relaying radio signals as in claim 12, further comprising the means for determining the signal weights by measuring the total energy of the radio frequency input.

16. An antenna extender for relaying radio signals as in claim 12, further comprising a means for shifting the output signal from one frequency to a different frequency.

17. An antenna extender for relaying radio signals as in claim 12, further comprising a means for amplification of the output signal.

18. An antenna extender for relaying radio signals as in claim 12, further comprising a means for caching of the signal.
